(19) United States
(12) Patent Application Publication
(10) Pub. No.: US 2009/0250784 A1
(43) Pub. Date: Oct. 8, 2009

(54) Structure and method for elimination of process-related defects in poly/metal plate capacitors

(75) Inventors: Walter B. Meinel, Tucson, AZ (US); Henry Surtihadi, Tucson, AZ (US); Philipp Steinmann, Richardson, TX (US); David J. Hannaman, Allen, TX (US)

Correspondence Address: TEXAS INSTRUMENTS INCORPORATED, P O BOX 655474, M/S 3999, DALLAS, TX, 75265, US

(73) Assignee: Texas Instruments Incorporated

(21) Appl. No.: 12/156,503

(22) Filed: Jun. 2, 2008

Related U.S. Application Data
(60) Provisional application No. 61/123,325, filed on Apr. 8, 2008.

(51) Int. Cl. H01L 29/94; H01L 21/02

(52) U.S. Cl. 257/516; 438/386; 257/E29.346; 257/E29.018; 257/E21.011; 257/E21.545

(57) ABSTRACT

An integrated circuit includes silicon layer (2) supported by a bottom oxide layer (3), a shallow trench oxide (4) in the shallow trench (30), and a polycrystalline silicon layer (5) on the shallow trench oxide. A deep trench oxide (25) extending from the shallow trench oxide to the bottom oxide layer electrically isolates a section (2A) of the silicon layer to prevent a silicon cone defect (22) on the silicon layer (2) from causing short-circuiting of the polycrystalline silicon layer (5) to a non-isolated section of the silicon layer. The polycrystalline silicon layer (5) can form a bottom plate of a poly/metal capacitor (20) and can also form a poly interconnect conductor (5A).

### CROSS REFERENCE TO RELATED APPLICATION

This application claims the benefit of prior filed co-pending U.S. provisional application Ser. No. 61/123,325 entitled “STRUCTURE AND METHOD FOR ELIMINATION OF PROCESS-RELATED DEFECTS IN POLY/METAL PLATE CAPACITORS”, filed Apr. 8, 2008 by Walter B. Meinel, Henry Surtihadi, Phillipp Steinmann, and David J. Hannaman, and incorporated herein by reference.

### BACKGROUND OF THE INVENTION

The present invention relates generally to methods and integrated circuit structures for avoiding the damaging effects of silicon cone defects.

Referring to FIG. 1, a known integrated circuit structure 1 includes a doped polycrystalline silicon (poly)/titanium nitride (TiN) plate capacitor, referred to herein as a poly/metal plate capacitor. The integrated circuit structure 1 is formed using a shallow trench isolation (STI) process. Integrated circuit structure 1 includes a bottom oxide layer 3 which is formed on the bottom surface of a single crystal silicon wafer substrate 8 and is sandwiched between oxide layer 3 and a support wafer 9. A N-type epitaxial silicon (epi) layer 2, the concentration of which can be approximately 3×10¹⁴ atoms per cubic centimeter, is formed on the upper surface of single crystal silicon substrate 8. A STI (shallow trench isolation) layer 4, which can be formed of SiO2, is formed on epitaxial layer 2. A P-type poly layer 5, which can be approximately 315 nanometers thick, and which can have a dopant concentration of approximately 1×10²⁰ atoms per cubic centimeter, is formed on epi layer 2 and serves as the lower plate of a poly/metal capacitor 20. A cobalt silicide layer, which performs the function of making the polycrystalline silicon more metallic so as to reduce the voltage coefficient of capacitance of poly/metal capacitor 20, is fused into the upper surface of poly layer 5 to form a poly silicide layer 6. A silane oxide capacitor dielectric layer 7, which can have a thickness of approximately 110 nanometers, is formed on poly silicide layer 6. A titanium nitride (TiN) layer 10, which can have a thickness of approximately 270 nanometers, is formed on capacitor dielectric layer 7. An oxide layer 12 is formed on titanium nitride layer 10. A metal top plate contact interconnect conductor 14 makes electrical contact to TiN top capacitor plate 10 by means of a tungsten via 15 that passes through a via opening in interlayer oxide layer 21 and a contact opening 11 in oxide layer 12 to contact titanium nitride layer 10. Similarly, a metal bottom plate interconnect conductor 16 makes electrical contact to poly bottom plate 5 of poly/metal capacitor 20 by means of a tungsten via 17 which passes through a corresponding via opening in interlayer oxide layer 21 and contacts poly silicide layer 6 of poly layer 5 through a contact opening 13 in capacitor dielectric layer 7. (Reference numeral 18 designates silicon nitride “spacers” which are “residuals” from producing the gates of CMOS transistors and perform no function.)

There are unavoidable micro-defects, commonly called “silicon cone defects”, which can appear or “grow” in epi layer 2 during a conventional shallow trench isolation (STI) etching process in which shallow trench regions 30 are etched into epitaxial layer 2. Reference numeral 22 in FIG. 1 shows a silicon cone defect. The silicon cone defects 22 are conductive, and consequently can electrically short-circuit the poly layer 5 (which functions as the bottom plate of poly/metal capacitor 20) to epi layer 2. Epi layer 2 ordinarily is biased at a relatively negative supply voltage, for example at ground voltage. Cone defects 22 are believed to be caused by defects in the epi layer due to contamination in the photoresist that determines the boundaries of the shallow trench regions 30 and by a selective etchant which is used to etch the shallow trench regions 30. STI etching processes which give rise to silicon cone defects are commonly utilized in state-of-the-art CMOS wafer fabrication processes. So far, it has not been possible to develop a silicon etchant which does not result in creation of cone defects.

An electrical short circuit caused by silicon cone defect 22 in FIG. 1 usually has very low impedance, and therefore can create “massive” failures such as causing sufficiently high current to flow through metal traces and through poly layer 5 into epi layer 2 so as to vaporize metal traces in the integrated circuit chip.

Thus, there is an unmet need for an integrated circuit process and an integrated circuit structure for avoiding damaging effects of silicon cone defects.

There also is an unmet need for an integrated circuit process and a poly/metal capacitor structure which avoid damaging effects of silicon cone defects.

There also is an unmet need for an integrated circuit process and a poly interconnect conductor or trace over a shallow trench isolation oxide structure which avoids damaging effects of silicon cone defects.

There also is an unmet need for a for a deep sub-micron integrated circuit process and integrated circuit structure which substantially improves integrated circuit yield.

There also is an unmet need for an integrated circuit cell, such as a digital logic library cell or an analog circuit library cell, including poly interconnect conductors or traces which pass over shallow trench isolation oxide, wherein short-circuiting of the poly traces to an underlying silicon conductor by silicon cone defects is avoided.

### SUMMARY OF THE INVENTION

It is an object of the invention to provide an integrated circuit process and an integrated circuit structure which avoid damaging effects of silicon cone defects.

It is another object of the invention to provide an integrated circuit process and a poly/metal capacitor structure which avoid short-circuiting of the poly plate of the poly/metal capacitor to an underlying silicon layer by a silicon cone defect.

It is another object of the invention to provide an integrated circuit process and a poly interconnect conductor or trace over shallow trench isolation oxide which avoids short-circuiting of the poly interconnect conductor or trace to an underlying silicon layer by a silicon cone defect.

It is another object of the invention to provide a deep sub-micron integrated circuit process and integrated circuit structure which substantially improve integrated circuit yield despite the presence of silicon cone defects therein.

It is another object of the invention to provide an integrated circuit cell, such as a digital logic library cell or an analog circuit library cell, including poly interconnect conductors or traces which pass over shallow trench isolation oxide, wherein the short-circuiting of the poly interconnect conductors or traces by silicon cone defects is avoided.

Briefly described, and in accordance with one embodiment, the present invention provides an integrated circuit which includes silicon layer (2) supported by a bottom oxide layer (3), a shallow trench oxide (4) in the shallow trench (30), and a polycrystalline silicon layer (5) on the shallow trench oxide. A deep trench oxide (25) extending from the shallow trench oxide to the bottom oxide layer electrically isolates a section (2A) of the silicon layer to prevent a silicon cone defect (22) on the silicon layer (2) from causing short-circuiting of the polycrystalline silicon layer (5) to a non-isolated section of the silicon layer. The polycrystalline silicon layer (5) can form a bottom plate of a poly/metal capacitor (20) and can also form a poly interconnect conductor (5A).

In one embodiment, the invention provides an integrated circuit structure (100/100A) including a bottom oxide layer (3), a single crystal silicon wafer substrate (8), and a silicon layer (2) on the silicon wafer substrate (8). A plurality of moat regions (33) of the silicon layer (2) extend upward from shallow trenches (30) in an upper surface (23 (FIG. 6a)) of the silicon layer (2). A shallow trench oxide layer (4) at least partially fills the shallow trenches (30), and a polycrystalline silicon layer (S) is formed on the shallow trench oxide (4). A deep trench oxide ring (25) extends between the shallow trench oxide (4) and the bottom oxide layer (3) to surround and electrically isolate a section (2A) of the silicon layer (2) from another section of the silicon layer (2), and prevents short-circuiting of the polycrystalline silicon layer (5) to the electrically isolated section (2A) of the silicon layer (2) by a silicon cone defect (22) in a shallow trench (30) in the silicon layer (2) from causing short-circuiting of the polycrystalline silicon layer (5) to any other section of the silicon layer (2). In the described embodiments, the silicon layer (2) is biased by means of a reference voltage (GND), and the deep trench oxide (25) and bottom oxide layer (3) prevent the silicon cone defect (22) in the electrically isolated section (2A) from causing the polycrystalline silicon layer (5) to be short-circuited to the reference voltage (GND). In the described embodiments, the silicon layer includes an epitaxial silicon layer (2).

In one embodiment, the polycrystalline silicon layer (5) forms a bottom plate of a poly/metal capacitor (20). A metal layer (10) is disposed over a capacitor dielectric layer (7) on the polycrystalline silicon layer (5) to form a top plate of the poly/metal capacitor (20). In interlayer oxide layer (21) is disposed on the capacitor dielectric layer (7), the polycrystalline silicon layer (5), the moat regions (33), and the shallow trench oxide layer (4). A first metal via (15) extends through the interlayer oxide layer (21) to electrically contact the metal layer (10), and a second metal via (17) extends through the interlayer oxide layer (21) to electrically contact the polycrystalline silicon layer (5). The metal layer (10) can be composed of titanium nitride. A top surface portion of the polycrystalline silicon layer (5) can include a cobalt silicide surface layer (6).

In one embodiment, the invention provides a method for preventing damage caused by short-circuiting of a polycrystalline silicon layer (5) on a shallow trench oxide layer (4) in a shallow trench (30) over a silicon layer (2) in an integrated circuit (100/100A), including providing a bottom oxide layer (3) which supports the silicon layer (2), etching a surface of the silicon layer (2) to provide a shallow trench (30) therein, etching a deep trench (31) from within the shallow trench (30) to the bottom oxide layer (3) to surround and isolate a section (2A) of the silicon layer (2), filling the deep trench (31) with deep trench oxide (25) and filling the shallow trench (30) with the shallow trench oxide layer (4), and forming the polycrystalline silicon layer (5) on the shallow trench oxide (4). This prevents the short-circuiting of the polycrystalline silicon layer (5) to the isolated section (2A) of the silicon layer (2) caused by a silicon cone defect (22) under the polycrystalline silicon layer (5) from also causing the polycrystalline silicon layer (5) to be short-circuited to any remaining section of the silicon layer (2).

In one embodiment, the invention provides an integrated circuit structure including a bottom oxide layer (3), a silicon layer (2) supported by the bottom oxide layer (3), a shallow trench (30) in a surface of the silicon layer (2) and shallow trench oxide layer (4) disposed in the shallow trench (30) and surrounding a plurality of moat regions (33) of the silicon layer (2), a polycrystalline silicon layer (5) on the shallow trench oxide layer (4), and deep trench means (25) for electrically isolating a section (2A) of the silicon layer (2) to prevent a silicon cone defect (22) on the silicon layer (2) from causing short-circuiting of the polycrystalline silicon layer (5) to a remaining section of the silicon layer (2).

### BRIEF DESCRIPTION OF THE DRAWINGS

FIG. 1 is a section view of a prior art integrated circuit poly/metal capacitor.

FIG. 2 is a section view of an integrated circuit structure which avoids the damaging effects of silicon cone defects in a poly/metal capacitor as shown in FIG. 1.

FIG. 3 is a section view of an integrated circuit structure including a polycrystalline silicon interconnect conductor that extends over shallow trench oxide, including a deep trench isolation structure that avoids short-circuiting, caused by a cone defect, of the polycrystalline silicon interconnect conductor to a supply voltage which biases an underlying silicon layer.

FIG. 4 is an equivalent circuit of the poly/metal capacitor 20 in FIG. 2.

FIG. 5 is a flow diagram of a process for making the integrated circuit structure shown in FIG. 2.

FIGS. 6a-6g constitute a sequence of section views of the poly/metal capacitor of FIG. 2 as it is fabricated using the process of the present invention.

### DETAILED DESCRIPTION OF THE PREFERRED EMBODIMENTS

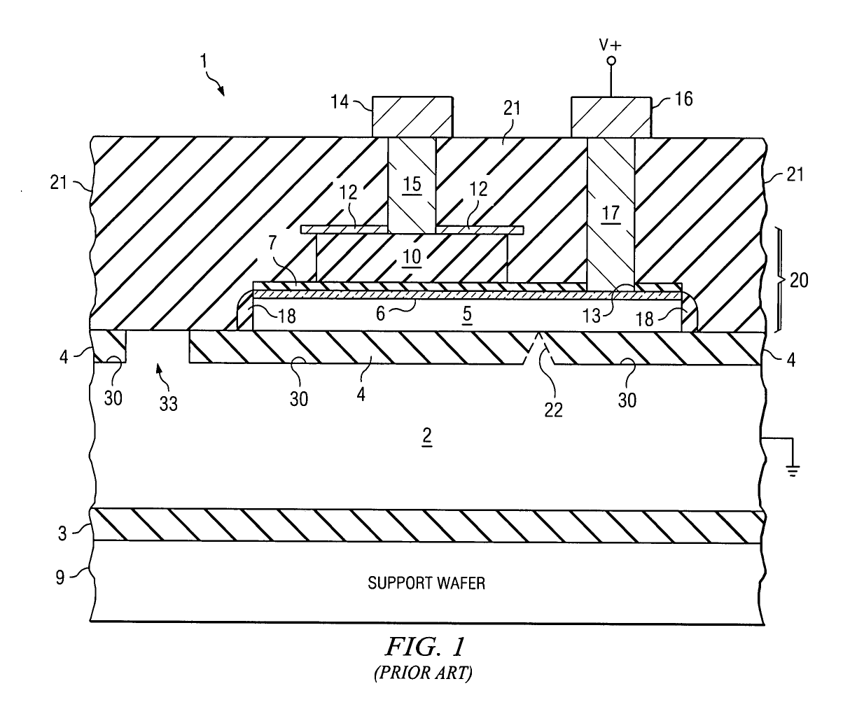

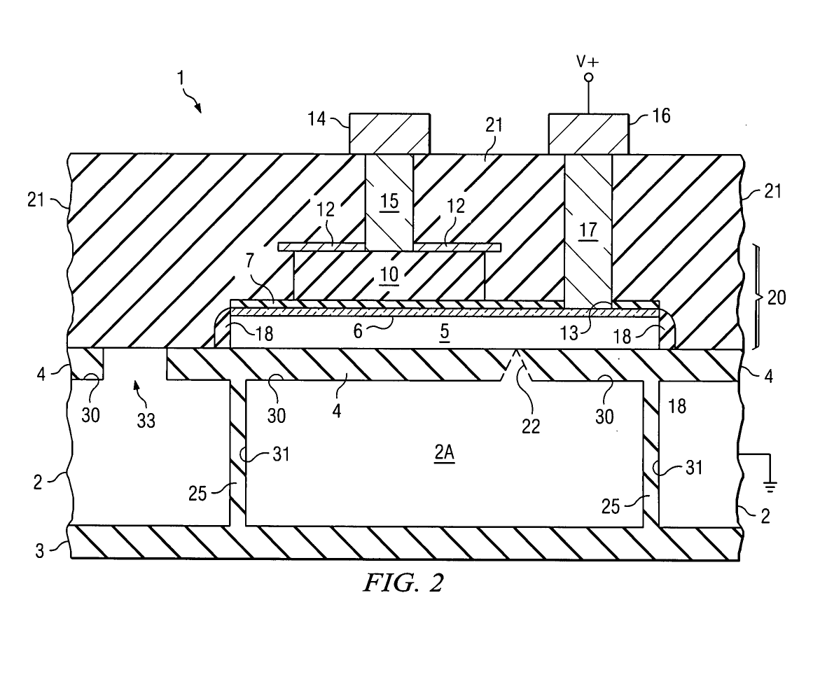

Referring to FIG. 2, integrated circuit structure 100 includes the same poly/metal plate capacitor 20 shown in Prior Art FIG. 1, which is formed using a shallow trench isolation (STI) process. Integrated circuit structure 100 in FIG. 2 is also formed using a shallow trench isolation process, and includes a bottom oxide layer 3 which is formed on the bottom surface of single crystal silicon wafer substrate 8. As in Prior Art FIG. 1, bottom oxide layer 3 is supported by a silicon support wafer (not shown) such as support wafer 9 in FIG. 1. A N-type epi layer 2 is formed on the upper surface of silicon substrate 8, as in Prior Art FIG. 1. Shallow trench oxide layer 4, which can be formed of SiO2, is formed on epi layer 2. The shallow trenches 30, in which shallow trench oxide layer 4 is formed, can be approximately 500 nanometers deep. Shallow trench oxide layer 4 preferably is of the same thickness as the shallow trench depth. P-type poly layer 5 is formed on shallow trench oxide layer 4, and serves as the lower plate of poly/metal capacitor 20. Poly layer 5 can be approximately 315 nanometers thick. A cobalt silicide layer is fused into the upper surface of poly layer 5 to form poly silicide layer 6 thereon. The silane oxide capacitor dielectric layer 7 is formed on poly silicide layer 6. Titanium nitride layer 10 is formed on capacitor dielectric layer 7.

Titanium nitride layer 10 can be approximately 270 nanometers thick. Oxide layer 12 is formed on titanium nitride layer 10. An inter-layer oxide layer 21 is formed on exposed upper surfaces of oxide layer 10, oxide layer 7, trench oxide layer 4, and moats 33. Metal top plate interconnect conductor or trace 14 on interlayer oxide 21 makes electrical contact to titanium nitride top capacitor plate 10 by means of tungsten via 15, which passes through a via opening in interlayer oxide 21 and a contact opening 11 in oxide layer 12. Similarly, metal bottom plate contact trace 16 makes electrical contact to poly bottom capacitor plate 5 by means of via 17, which passes through a via opening in interlayer oxide 21 and a contact opening 13 in capacitor dielectric layer 7 and contacts poly silicide layer 6 as shown in Prior Part FIG. 1, wherein the silicon cone defect 22 short-circuits supply voltage V+ to ground through poly layer 5 and epitaxial layer 2.

In accordance with the present invention, a deep trench (DT) 31 that circumscribes epi region 2A is etched through epitaxial layer 2 and silicon substrate 8 to bottom oxide layer 3 and then is filled with a deep trench oxide “ring” 25 that circumscribes a section 2A of epitaxial layer 2 so that it is electrically isolated from the rest of epitaxial layer 2. Consequently, even though the rest of epitaxial layer 2 is biased at ground voltage, isolated section 2A of epitaxial layer 2 is isolated from the ground voltage and therefore assumes the same voltage as poly layer 5 if poly layer 5 is electrically short-circuited to epi layer 2 by a cone defect 22. That is, deep trench 25 oxide electrically disconnects the poly bottom plate 5 of poly/metal capacitor 20 from the ground voltage of epi layer 2 irrespective of whether poly layer 5 and the isolated poly section 2A are electrically short-circuited together by a cone defect 22.

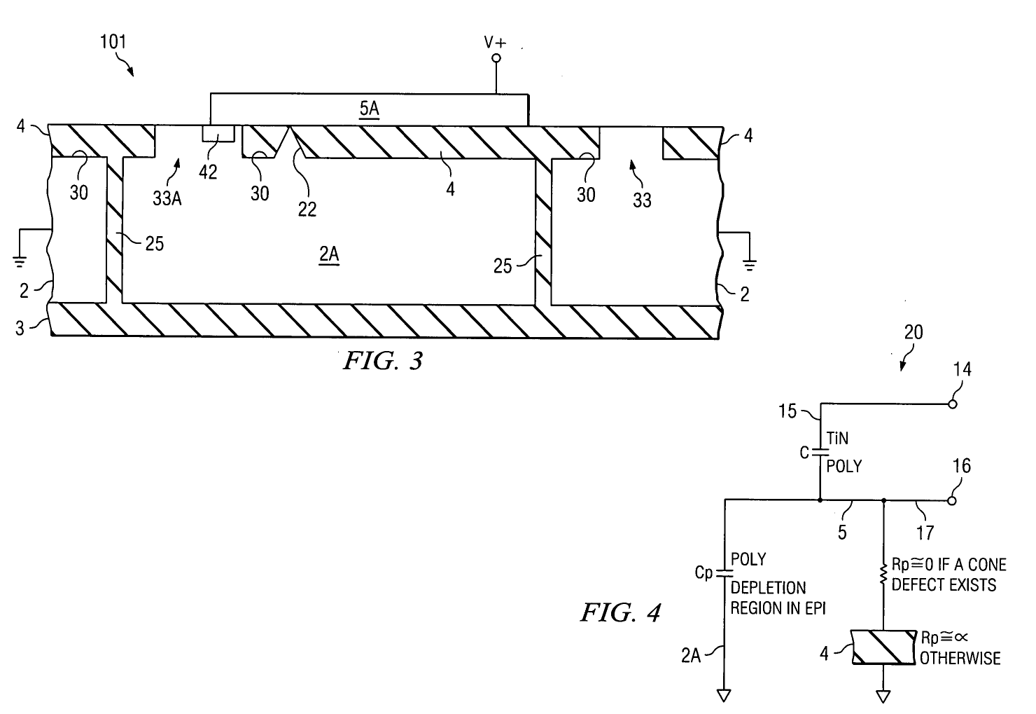

FIG. 3 shows another embodiment of the invention, wherein integrated circuit structure 100A includes the same configuration of bottom oxide 3, silicon substrate 8, epi layer 2, isolated section 2A of N-type epi layer 2, deep trench oxide 25, and shallow trench oxide 4 as shown in FIG. 3. Various moats such as 33 and 33A in FIG. 3 extend from shallow trench 30 up to a planar surface at the top level of moats 33 whereon a poly interconnect conductor 5A is disposed. A cone defect 22 can be present anywhere in any shallow trench 30 which has been etched using a conventional STI (shallow trench isolation) photoresist process and etching process. Shallow trench oxide 4 has been deposited in the shallow trenches 30, continuous with deep trench oxide 25 which electrically isolates section 2A of epi layer 2. Conductive poly interconnect conductor 5A can be connected to a transistor electrode, such as a P-type source region 42 of a P-channel MOSFET (not shown) that has been formed in moat 33A. If a cone defect 22 is present, it short-circuits interconnect conductor 5A to epi layer section 2A. If epi section 2A were not isolated by deep trench isolation oxide 25 in the manner shown in FIG. 3 and instead were continuous with the rest of epi layer 2 as in Prior Art FIG. 1, then poly trace 5A would be short-circuited to ground by any silicon cone defect 22 which happens to be directly underneath it. In a worst-case situation, poly trace 5A is connected to a positive power supply voltage V+ as shown in FIG. 3, in which case cone defect 22 short-circuits the positive power supply voltage V+ to the ground power supply voltage, causing a very large current to flow through poly trace 5A and silicon cone defect 22, probably vaporizing the metallization (not shown) connecting poly trace 5A to V+ and thereby destroying the integrated circuit. Providing the deep trench isolation “ring” 25-1 circumscribing epi region 2A as shown in FIG. 3 prevents the short-circuiting of poly interconnect conductors to ground irrespective of the presence of cone defects 22.

It should be appreciated that the cone defects can occur anywhere in any STI-etched trench 30, and may cause substantially decreased integrated circuit chip manufacturing yields.

FIG. 4 shows an equivalent circuit of metal/poly capacitor 20 in FIG. 2. Poly/metal capacitor 20 consists of an intrinsic capacitor having a capacitance C and a parasitic capacitor having a capacitance Cp with a typical value of approximately 0.2 C connected between poly layer 5 and ground. Parasitic capacitor Cp shares the bottom poly plate 5 of poly/metal capacitor 20 as a first plate and also includes the deep-trench-isolated epi layer 2A as a second plate.

There is also a resistive path Rp between poly layer 5 and epitaxial layer 2A having a nearly infinite resistance if poly/metal capacitor 20 is free of any cone defects. However, if there is a cone defect 22 contacting poly layer 5, then the resistance of parasitic resistive path Rp can be very close to zero. However, with the addition of deep trench oxide ring 20 formed under epi region 2A under poly/metal capacitor 20 in accordance with the present invention, the resistance of Rp is nearly infinite irrespective of whether a cone defect 22 is present, because the deep trench ring 20 electrically isolates epi layer section 2A from the ground voltage applied to epitaxial layer 2 irrespective of whether a cone defect is present.

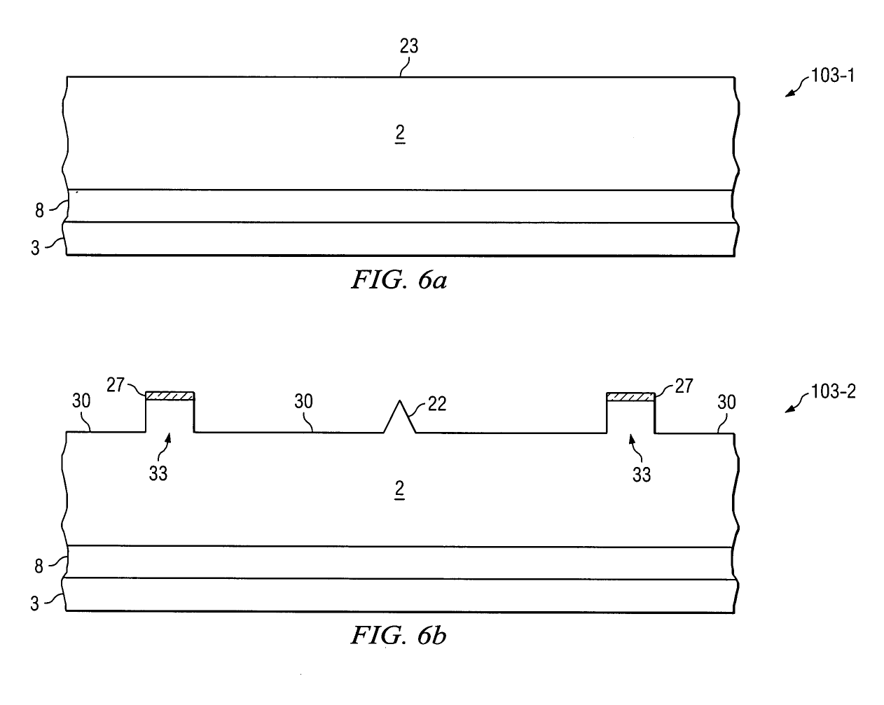

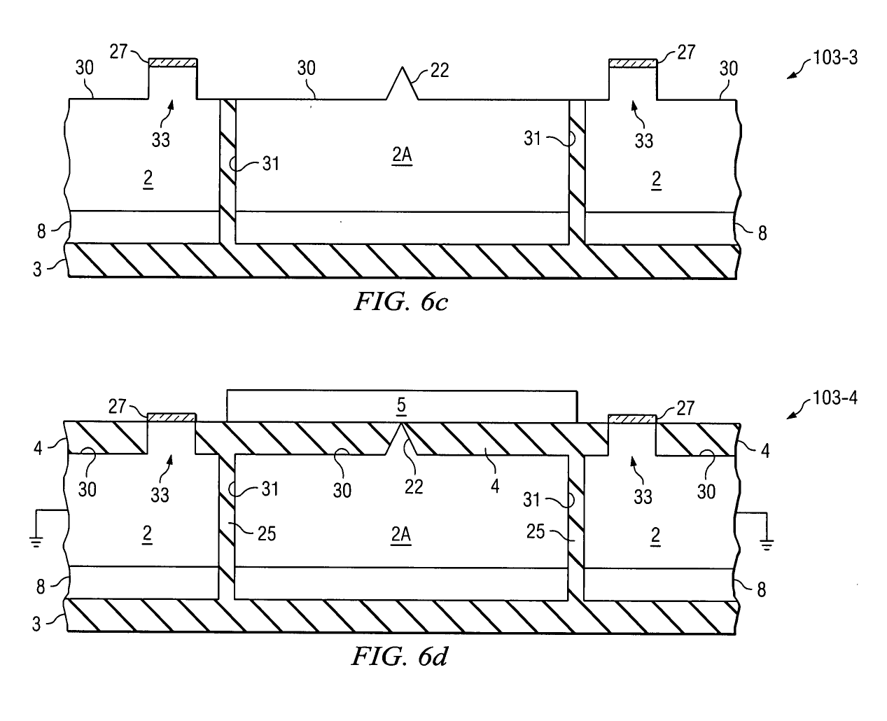

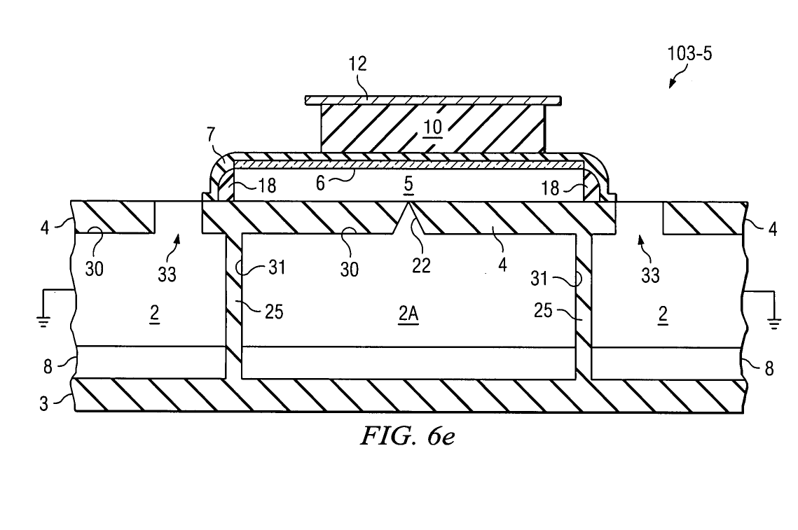

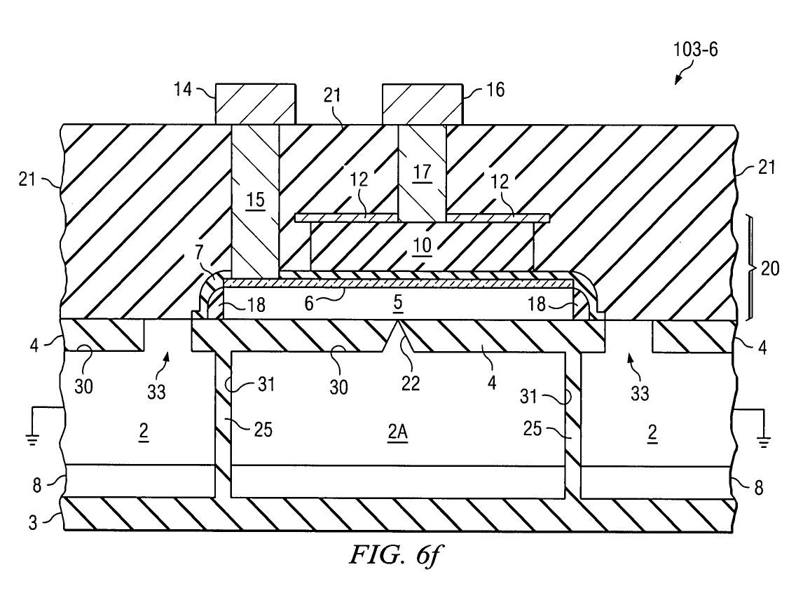

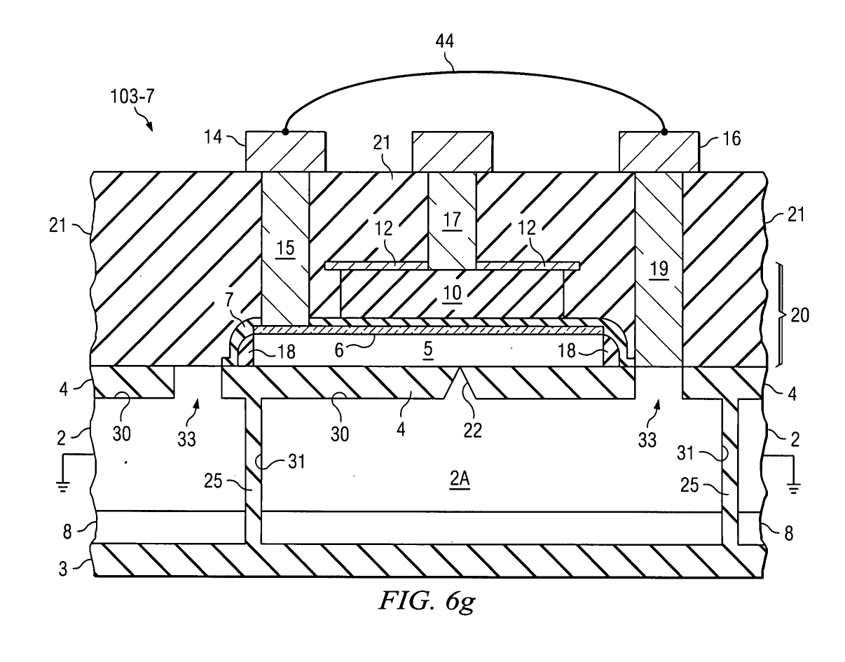

The ratio of the parasitic capacitance Cp to the intrinsic capacitance C typically is a approximately 0.2, and is essentially independent of the dopant concentration in the range of interest for epitaxial layer 2,2A. Note that if there is a short circuit caused by a cone defect 22, then the parasitic capacitance Cp will increase from 0.2 C to approximately 0.25 C, which ordinarily will be insignificant in many circuit applications. However, if the variation of parasitic capacitance Cp due to the presence of a short-circuit caused by a cone defect 22 unacceptable for a particular integrated circuit containing poly/metal capacitor 20, then the poly/metal capacitor 20 can be connected to the poly layer 5 in the manner shown in subsequently described FIG. 6g. In this case, the parasitic capacitance Cp is always equal to a constant value of 0.25 C.

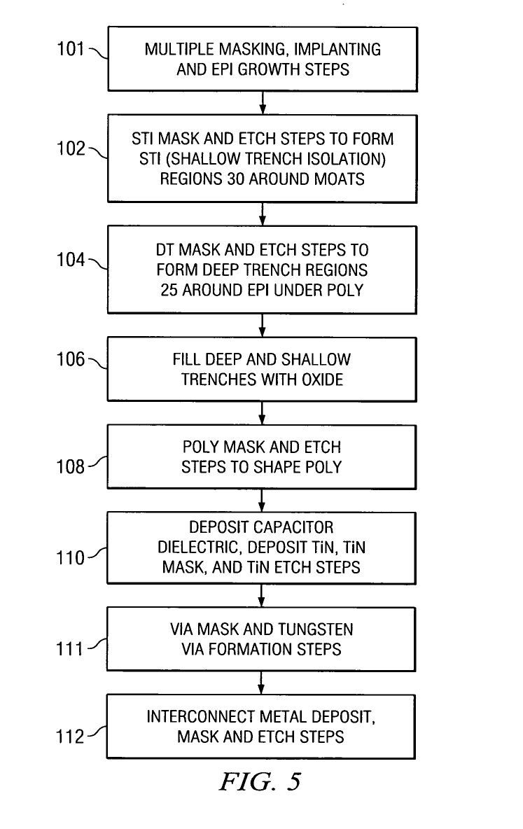

FIG. 5 shows a flow diagram of a process for making the integrated circuit structure 100 shown in FIG. 2. FIGS. 6a-6f show a sequence of section views of the metal/poly capacitor structure 100 of FIG. 2 as it is fabricated using the process described below. Referring to block 101 of FIG. 5, various conventional processes are performed, including providing single crystal silicon layer 8 on bottom oxide 3, growing one or more epitaxial layers such as 2 on silicon layer 8, and also various ion implanting processes and associated photo masking processes are performed to provide a wafer structure 103-1 having a planar top surface 23, as generally indicated in FIG. 6a.

Referring to block 102 of FIG. 5, a shallow trench isolation (STI) etch process is performed to define the shallow trench areas 30 as shown in FIG. 6b, after a suitable masking operation to define multiple moat regions 33. Layer 27 in FIG. 6b can be a silicon nitride “hard mask” layer. Various cone defects such as 22 may appear on the upper surface of epitaxial layer 2 during the etching of shallow trench regions 30 in epi layer 2, possibly as a result of microscopic defects associated with the STI process. The shallow trench regions 30 laterally separate the moat regions 33 and reduce associated parasitic capacitances, and also limit undesired lateral diffusions such as collector “sinkers” (which are deep diffusions that limit the amount of lateral diffusion of either N-type or P-type implants (not shown)) which may occur as bipolar transistors are subsequently formed in some of the moat regions 33.

Referring to block 104 in FIG. 5 and FIG. 6c, the fabrication process includes depositing an oxide mask on the wafer surface. A suitable photoresist coating is spun onto the wafer surface. A deep trench (DT) photoresist mask is applied to define the regions where deep trenches 31 are to be etched. The oxide exposed by the oxide mask and then is etched using an appropriate silicon etchant to form a deep trench ring 31 all the way through epi layer 2 to bottom oxide layer 3, as shown in FIG. 6c. The photoresist then is removed.

Next, referring to block 106 of FIG. 5, the fabrication process includes depositing a deep trench oxide fill 25 in the deep trench isolation regions 31 and a shallow trench oxide fill 4 in the shallow trench regions 30, as shown in FIG. 6d. This circumscribes and hence isolates epi layer section 2A from the rest of epi layer 2. The trench oxide 4 preferably provides a planar upper surface of the wafer structure 103-4 prior to formation of poly layer 5, and also provides lateral oxide isolation between the various moat regions 33, into which devices such as transistors may be formed and/or onto which poly interconnect conductors or traces may be formed. (Note that the etching of the shallow trenches 30 does not remove any of the silicon cone defects 22, which extend up from the silicon of epi layer 2 at the bottoms of shallow trenches 30 after the shallow trench etching is completed. The shallow trench oxide 4 fills in the trench area 30 around both the moat regions 33 and the cone defects 22.)

Next, the P-type poly layer 5 shown in FIG. 6d is deposited on shallow trench oxide 4. A cobalt silicide is fused to the top of poly layer 5 by means of a silicidation process which creates a poly silicide layer 6 on poly layer 5. Note that any cone defect 22 which appears after the shallow trench etching process is of the same height as the moat regions 33. Therefore, the tip of a cone defect touches the bottom of poly layer 5 and therefore short-circuits it to the top of epi layer 2.

As indicated in block 108 of FIG. 5, the next step in the fabrication process is a poly etching process, wherein a poly mask defines the shapes of the bottom plate 5 of metal/poly capacitor 20 (FIG. 2) and the poly silicide layer 6 thereon, as shown in FIG. 6e. The poly mask and poly etching process also can define the shapes of gate electrodes of MOS transistors (not shown) that can be formed in the various moat regions, and can also define the shapes of poly interconnect conductors such as 5A on the shallow trench oxide 4 as shown in FIG. 3.

As indicated in FIG. 6e and in block 110 of FIG. 5, the wafer fabrication includes depositing a high-quality capacitor dielectric layer 7 on cobalt silicide layer 6. Then a titanium nitride top plate layer 10 is deposited on dielectric layer 7. An oxide layer 12 is deposited on titanium nitride layer 10 and functions as a mask for etching titanium nitride layer 10 to form a top plate of poly/metal capacitor 10. The resulting structure 103-5 is shown in FIG. 6e.

Referring to block 111 of FIG. 5 and to FIG. 6f, a via masking process is performed to define the locations of via openings in an interlayer oxide layer 21 for tungsten vias 15 and 17 which pass through interlayer oxide layer 21, which has been deposited on the structure 103-5 in FIG. 6e, to via contact areas on tungsten nitride layer 10 and poly silicide layer 6. Then a tungsten layer deposition process and an associated etching process are performed to form the vias 15 and 17 in the via openings. Finally, a interconnect metallization deposition in etching process is performed to provide the metal interconnect conductors 14 and 16 which contact the tops of tungsten vias 15 and 17, respectively.

Alternatively, the deep trench 31 and deep trench oxide 25 can be configured to surround one of moat regions 33, and the metal interconnect conductor 16 can be configured to also contact isolated epitaxial region 2A through an additional tungsten via 19 in the structure 103-7 as shown in FIG. 6g, wherein the additional tungsten via 19 is electrically short-circuited to metal 14 conductor by a conductor 44 (which can be implemented by means of metallization in the same layer as conductors 14 and 16 or by means of metallization in a different layer). This structure results in the previously mentioned constant value of the parasitic capacitance Cp associated with metal/poly capacitor 20, irrespective of whether there is a short circuit caused by a cone defect. The steps in blocks 101, 102, 104, 106 and 108 in FIG. 5 can be used to produce the structure shown in FIG. 3.

The invention thus provides a structure having a poly layer on a shallow trench oxide, wherein cone defects in an epi layer under the shallow trench oxide can short-circuit the poly layer to epitaxial layer. Poly layers are used to form bottom plates of poly/metal capacitors in one embodiment of the invention. In another embodiment of the invention, poly conductors on shallow trench oxide are used as interconnect conductors. In all embodiments of the invention, a deep trench isolation regions surround of sections of an epi layer directly below the poly capacitor top plates layers or poly interconnect conductors so as to electrically isolate the immediately underlying sections of the epi layer from the rest of the epi layer. This prevents the poly capacitor top plates and/or poly interconnect conductors from being short-circuited to a bias voltage applied to the rest of the epi layer, irrespective of the presence or absence of silicon cone defects which short-circuit the poly capacitor top plates and/or poly interconnect conductors to the electrically isolated sections of the epi layer.

While the invention has been described with reference to several particular embodiments thereof, those skilled in the art will be able to make various modifications to the described embodiments of the invention without departing from its true spirit and scope. It is intended that all elements or steps which are insubstantially different from those recited in the claims but perform substantially the same functions, respectively, in substantially the same way to achieve the same result as what is claimed are within the scope of the invention.

What is claimed is:

1. An integrated circuit structure comprising:
(a) a bottom oxide layer;
(b) a silicon layer supported by the bottom oxide layer;
(c) a plurality of moat regions of the silicon layer extending upward from shallow trenches in an upper surface of the silicon layer;
(d) a shallow trench oxide layer at least partially filling the shallow trenches;
(e) a polycrystalline silicon layer on the shallow trench oxide; and
(f) a deep trench oxide ring extending between the shallow trench oxide and the bottom oxide layer to surround and electrically isolate a section of the silicon layer from another section of the silicon layer wherein short-circuiting of the polycrystalline silicon layer to the electrically isolated section of the silicon layer by a silicon cone defect in a shallow trench in the silicon layer is prevented from short-circuiting the polycrystalline silicon layer to any non-isolated section of the silicon layer.

2. The integrated circuit structure of claim 1 wherein the electrically isolated section of the silicon layer includes a silicon cone defect extending through the shallow trench oxide layer and short-circuiting the polycrystalline silicon layer to the isolated section.

3. The integrated circuit structure of claim 2 wherein the silicon layer is biased by means of a reference voltage, and the deep trench oxide and bottom oxide layer prevent the silicon cone defect in the electrically isolated section from causing the polycrystalline silicon layer to be short-circuited to the reference voltage.

4. The integrated circuit structure of claim 1 wherein the silicon layer includes an epitaxial silicon layer.

5. The integrated circuit structure of claim 1 wherein the polycrystalline silicon layer forms a bottom plate of a poly/metal capacitor.

6. The integrated circuit structure of claim 5 including a metal layer disposed over a capacitor dielectric layer on the polycrystalline silicon layer to form a top plate of the poly/metal capacitor.

7. The integrated circuit structure of claim 6 including an interlayer oxide layer disposed on the capacitor dielectric layer, the polycrystalline silicon layer, the moat regions, and the shallow trench oxide layer, a first metal via extending through the interlayer oxide layer to electrically contact the metal layer, and a second metal via extending through the interlayer oxide layer to electrically contact the polycrystalline silicon layer.

8. The integrated circuit structure of claim 6 wherein the metal layer is composed of titanium nitride.

9. The integrated circuit structure of claim 1 wherein a top surface portion of the polycrystalline silicon layer includes a silicide surface layer.

10. The integrated circuit structure of claim 10 wherein the silicide surface layer is composed of cobalt silicide.

11. The integrated circuit structure of claim 4 wherein the epitaxial silicon layer is a N-type layer, and wherein the polycrystalline silicon layer is a P-type polycrystalline silicon layer.

12. The integrated circuit structure of claim 1 wherein the polycrystalline silicon layer is approximately 315 nanometers in thickness.

13. The integrated circuit structure of claim 1 wherein the shallow trench oxide layer is approximately 500 nanometers in thickness.

14. The integrated circuit structure of claim 8 wherein the titanium nitride is approximately 270 nanometers in thickness.

15. A method for preventing damage caused by short-circuiting of a polycrystalline silicon layer through a shallow trench oxide layer in a shallow trench in a silicon layer in an integrated circuit, the method comprising:
(a) providing a bottom oxide layer which supports the silicon layer;
(b) etching a surface of the silicon layer to provide a shallow trench therein;
(c) etching a deep trench from within the shallow trench to the bottom oxide layer to surround and isolate a section of the silicon layer;
(d) filling the deep trench with oxide and filling the shallow trench with the shallow trench oxide layer; and
(e) forming the polycrystalline silicon layer on the shallow trench oxide,
to thereby prevent short-circuiting of the polycrystalline silicon layer to the isolated section of the silicon layer by a silicon cone defect under the polycrystalline silicon layer from also causing short-circuiting of the polycrystalline silicon layer to any non-isolated section of the silicon layer.

16. The method of claim 15 including depositing a dielectric oxide over the polycrystalline silicon layer and depositing a metal layer on the dielectric oxide, whereby the polycrystalline silicon layer, the dielectric oxide layer, and the metal layer form a poly/metal capacitor.

17. The method of claim 16 including shaping the polycrystalline silicon layer to form an interconnect conductor coupled between a circuit element region in a moat region of the silicon layer and a voltage that is substantially greater than a reference voltage applied to the silicon layer.

18. An integrated circuit structure comprising:
(a) a bottom oxide layer;
(b) a silicon layer supported by the bottom oxide layer;
(c) a shallow trench in a surface of the silicon layer and shallow trench oxide layer disposed in the shallow trench and surrounding a plurality of moat regions of the silicon layer;
(d) a polycrystalline silicon layer on the shallow trench oxide layer; and
(e) deep trench means for electrically isolating a section of the silicon layer to prevent a silicon cone defect on the silicon layer from causing short-circuiting of the polycrystalline silicon layer to a non-isolated section of the silicon layer.

19. The integrated circuit structure of claim 18 wherein the polycrystalline silicon layer forms a bottom plate of a poly/metal capacitor.

20. The integrated circuit structure of claim 18 wherein the polycrystalline silicon layer is an interconnect conductor coupled between a circuit element region in one of the moat regions and a voltage that is substantially greater than a reference voltage applied to the silicon layer.
